(19) United States
(12) Patent Application Publication
(10) Pub. No.: US 2010/0033936 A1
(43) Pub. Date: Feb. 11, 2010

(54) Method and apparatus for rapid and dynamic RF and microwave circuit prototyping and integration

(76) Inventors: Jenny Jiayan Shen, Chapel Hill, NC (US); Yong Su, Plano, TX (US); Zhunming Du, Cary, NC (US); Ying Shen, Chapel Hill, NC (US)

Correspondence Address: Ying Shen, 100 River Birch Lane, Chapel Hill, NC, 27514, US

(21) Appl. No.: 12/228,130

(22) Filed: Aug. 11, 2008

(51) Int. Cl. H05K 7/00; H05K 1/14

(52) U.S. Cl. 361/729; 361/736

(57) ABSTRACT

A method and apparatus for rapid and dynamic RF and Microwave circuit prototyping and integration provides a standard test fixture for testing any single device from any device vendors, provides a rapid dynamic tool for sub-system and system integration and prototyping, provides a flexibility to make any single function or multi-function assembled module quickly and economically. This prototyping approach can help RF/microwave companies share development times and costs. The combination of standard PCB function cells and dynamic standard mechanical cells helps build a prototype design quickly and reduce R&D costs.

### BRIEF DESCRIPTION OF THE DRAWING

FIG. 1 is a single standard cell test fixture. 110 is a single mechanical cell; 120 is a single PCB cell; and 130 is an assembled single cell test fixture.

FIG. 2 is a large single cell test fixture, where a large single cell can be any multiple cells of a single standard cell. 210 is a single 2×3 size PCB cell; 220 is a single joint cell; 230 is an assembled 2×3 mechanical cell, which is made of 6 single mechanical cells and single joint cells; and 240 is an assembled 2×3 cell test fixture.

FIG. 3 is a single assembled module. 310 is a single mechanical base with four side walls; 320 is an exposed view with a cover, in/out connectors, screws, and a mounting bracket; and 330 is an assembled module.

FIG. 4 is a dynamic assembled test fixture, where test fixtures of any shape can be made by the combination of single mechanical cells and single joint cells. 410 is the front side of a dynamic test fixture; and 420 is the back side of the dynamic test fixture. For test convenience, the single mechanical cell can also hold standoffs.

FIG. 5 is an example of a transmitter dynamic block diagram.

FIG. 6 is the test fixture based on FIG. 5 block diagram. 610 is the front side of the test fixture; and 620 is the back side of the test fixture.

FIG. 7 is the array test fixture. 710 is a single 5×5 array cell; 720 is an array joint cell; and 730 is a dynamic larger array, which is made of single array cells and array joint cells to have the same system as shown in FIG. 5.

FIG. 8 is a single assembled array module. 810 is a single 5×5 mechanical array cell with four side walls; 820 is a cover; 830 is an assembled module.

### DESCRIPTION OF THE PREFERRED EMBODIMENT

With reference to the figures where like elements have been given like numerical designations to facilitate an understanding of the present subject matter, the various embodiments of a method and apparatus for RF and rapid and dynamic RF and microwave prototyping and integration are herein described.

The present subject matter generally describes as a method and apparatus for rapid and dynamic Radio Frequency (“RF”) and Microwave circuit prototyping and integration. The prototyping and integration are adaptable to operate in the frequency range of DC-60 GHz. They may be used for RF and Microwave circuit applications. The RF and Microwave circuit prototyping and integration may be generally configured as a mechanical base (or enclosure) and a Printed Circuit Board (PCB). Interconnections between a mechanical base (or enclosure) and a PCB may generally be by various screws. The RF and Microwave circuit prototyping and integration may be optimized for a single standard mechanical cell and a single standard PCB cell. The single standard mechanical cell may be designed to be expandable to any shape by connecting with many standard single mechanical cells and single joint cells. Furthermore, the single standard mechanical cell may also be added standard sidewalls and standard covers to have assembled modules via connecting with screws. The standard sidewalls may include connectors, bias feed-through capacitors and grounding poles. Furthermore, taking into consideration the cost and time to market, a 5×5 standard array cell fixture may also be introduced for larger system integration applications. Standard 5×5 array cells may be expanded to an even larger array by connecting with standard array joint elements. A standard PCB cell may have a standard dimension such as 20×20 mm², a standard input/output location such as the center of the cell for easier connection between various cells, a standard Direct Current (DC)/control line connector at a fixed location. A larger PCB cell as long as the multiple dimension of a single cell may also be designed for a large footprint or a complex device. A library of standard cell PCBs may be designed and offered based on the most commonly used off-the-shelf devices from various vendors. Customers may use standard single or any combination of these PCB cells with standard mechanical single cells or dynamic mechanical cells (combination of single mechanical cells) or array cells to build rapidly to have their needed subsystem or systems in a fraction of the traditional cost and time. Customers may also use the single cell with selected standard sidewalls and covers to build their preferred modules in hours.

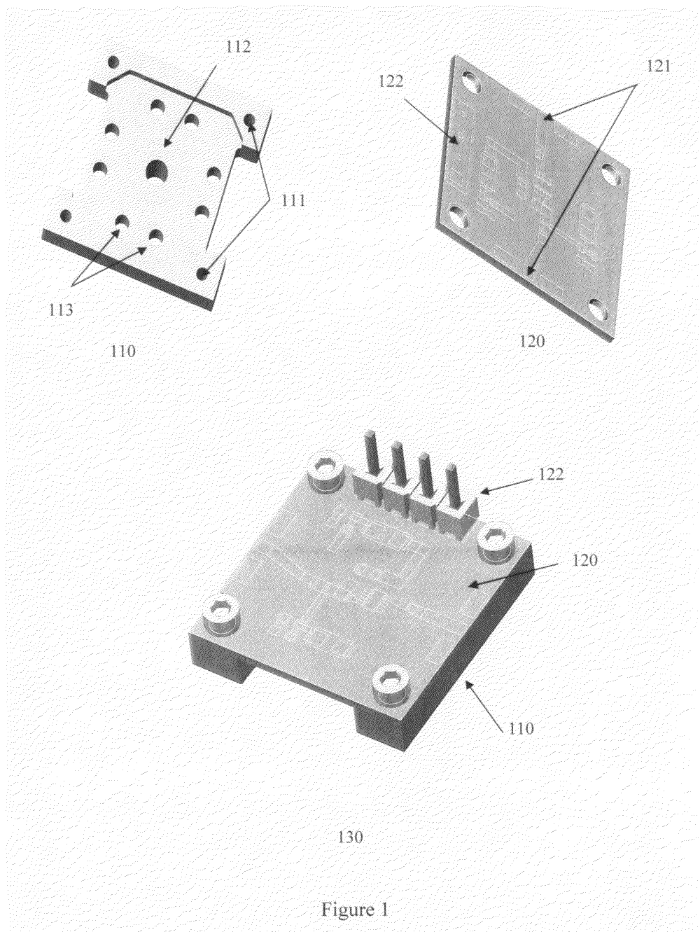

FIG. 1 shows the basic elements of the rapid RF and microwave prototyping concept. With reference to FIG. 1, basic elements for RF/Microwave circuit prototyping generally comprise a single standard mechanical cell 110 and a single standard PCB cell 120. The single standard size is 20×20 mm². 111 (qty.4) are the screw holding places for mounting standard PCB cells; 112 is a screw space for a standoff if needed; 113 (qty.8) are the screw spaces for either sidewalls 311 or single joint cells 220, which will be further described in the description below. In a standard PCB cell 120, 121 is the input and output locations which should always be at the center of a single cell, which is designed to have the common input/output locations for all the standard PCB cells. 122 is the location of the common connector for DC and controlling pins. The location and the type of the connector (122) are common for standard PCB cells; however, each PCB cell can have two or more connectors (maximum 4 connectors). The standard single test fixture 130 includes a single standard mechanical cell 110 and a single standard PCB cell 120.

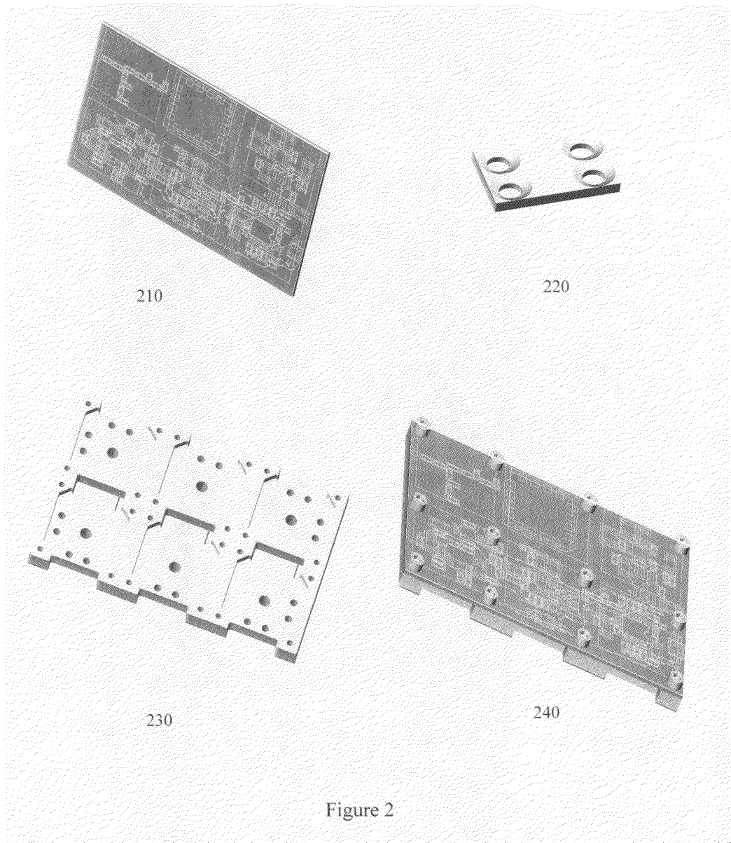

FIG. 2 is a 2×3 synthesizer cell. 210 is a 2×3 synthesizer PCB cell, 220 is a standard joint cell; 230 is a 2×3 mechanical base which comprises 6 single standard mechanical cells with a few standard joint cells; and 240 is a 2×3 synthesizer test fixture. The aforementioned synthesizer example and 2×3 multiples are exemplary only. A standard large cell can be designed as long as its overall dimension equaling the integral multiples of a standard single cell dimension. Of course, the input/output, DC/control connector locations should also be respected according to the single cell standard locations.

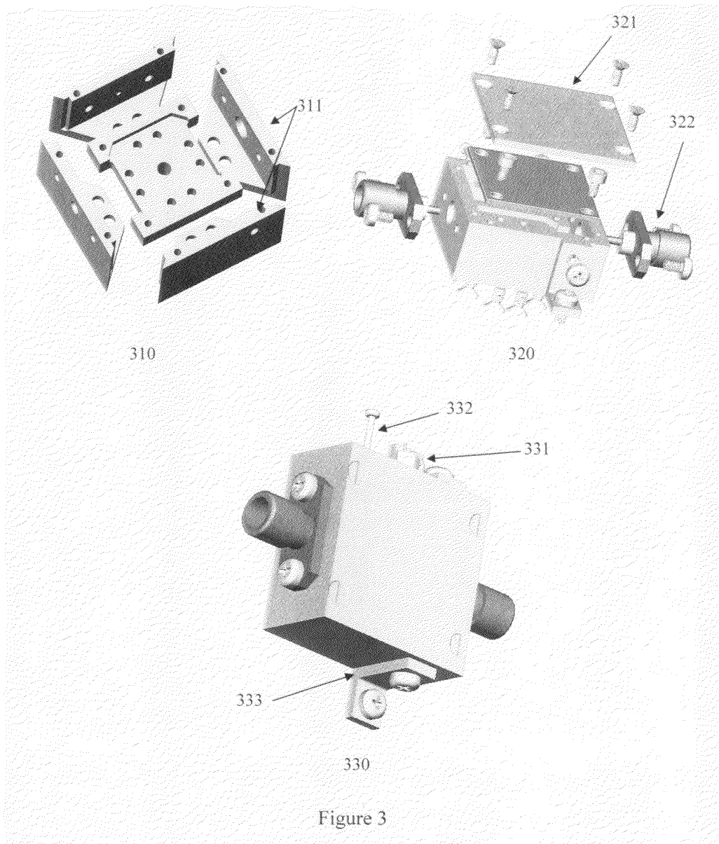

FIG. 3 is a single assembled amplifier module. With reference to FIG. 3, a single assembled module may generally comprise of one single base cell, one PCB cell, four selected sidewalls and one cover; however, such is just an example regarding the module function; the number of input and output, the number of base cell, the number of PCB cells, sidewalls and covers can be very dynamic and flexible based on the customer needs. 310 is a single base with four selected standard sidewalls 311; 320 is an exploded view for an assembled module which may include input/output connectors 322, cover 321, mounting bracket 333, feed through capacitor 331 and grounding solder terminal 332; 330 is a complete assembled amplifier module.

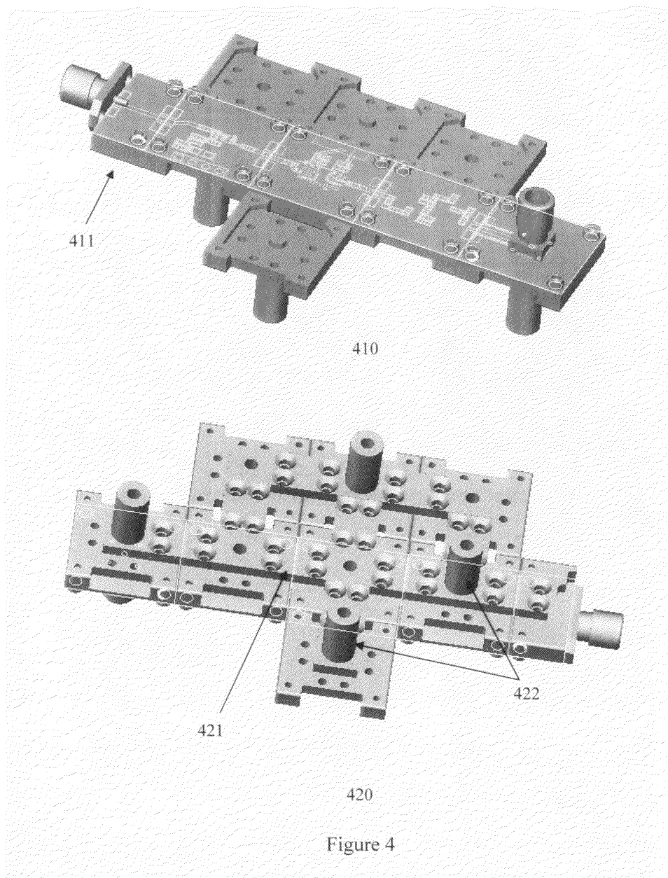

There are unlimited possibilities of using the proposed dynamic prototyping concept such as the example of a small dynamic circuitry shown in FIG. 4. With reference to FIG. 4, any shape and any size may be made of single standard mechanical cells, single standard joint cell with standard PCB cells. For convenience of the launch and the better grounding, a half standard cell may also be introduced with a standard half launch PCB cell. Furthermore, the standard single mechanical cell may also connect to standoffs in the center of each single mechanical cell for overall dynamic test fixture to properly stand. 410 shows the front side of the test fixture and 420 shows the back side of the test fixture. 411 is an input half launch cell, 421 is the standard single joint cell and 422 is the standoff. Embodiment of the present subject matter may employ various dynamics regarding the shape and size.

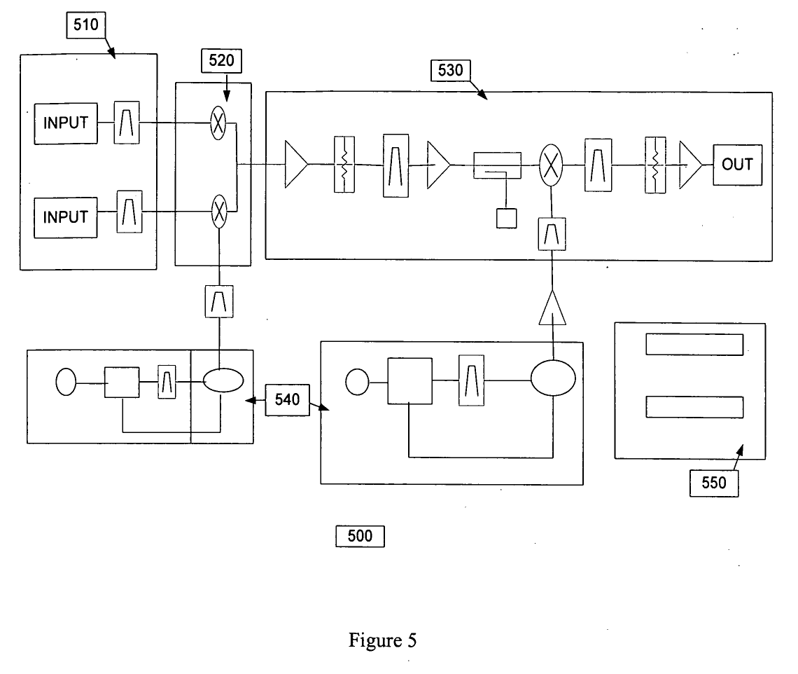

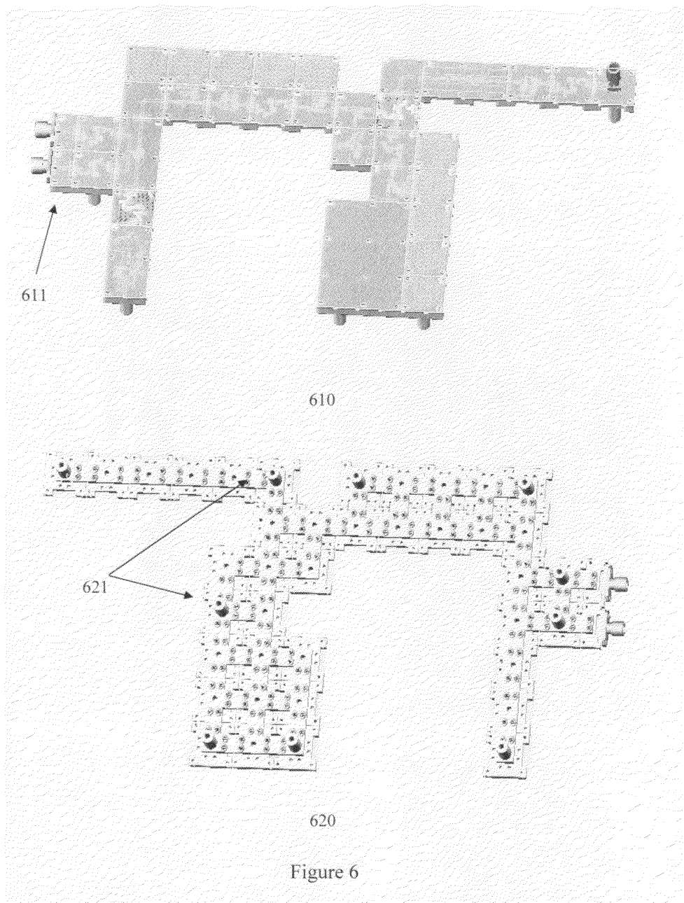

FIG. 5 further shows an example of a detailed transmitter using the dynamic prototyping concept. With reference to FIG. 5, a transmitter 500 may generally comprise of four primary functional blocks including, but not limited to, an I/Q data input ports 510, a first up-converter or modulator 520, a second up-converter including various stages of amplifiers, filters, attenuators, mixer and power amplifiers 530, and synthesizers 540. With reference to FIG. 5, and using the prototyping concept according to an embodiment of the present subject matter by selecting various offered PCB cells and connecting the standard single mechanical cells and standard joint cells, a transmitter system may be built in a very quick manner as shown in FIG. 6. 610 is the front side of the transmitter system and 620 is the back side of the transmitter. The input standard half launch cell 611 may also be used as well as the standoffs 621. Again, such a transmitter system is just an example.

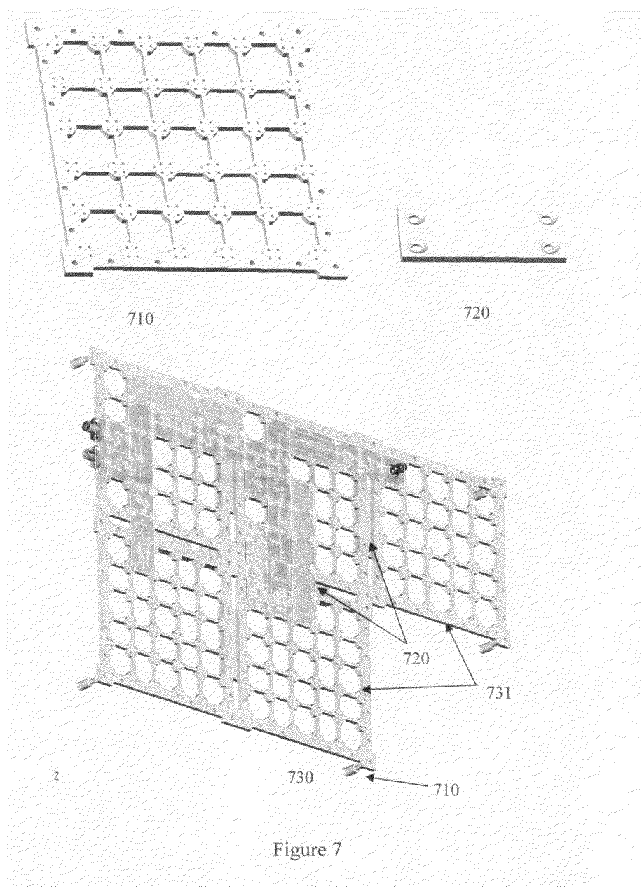

An additional embodiment of the present subject matter provides a 5×5 array mechanical cell 710, an array joint 720 as shown in FIG. 7. The standoff 731 may also be used. Such an array test fixture further provides the cost and time benefits for a large system's prototyping and integration. 730 shows an example using the block diagram of 500 to achieve the same results as 610 and 620. Again, here the array size of 5×5 is just an example.

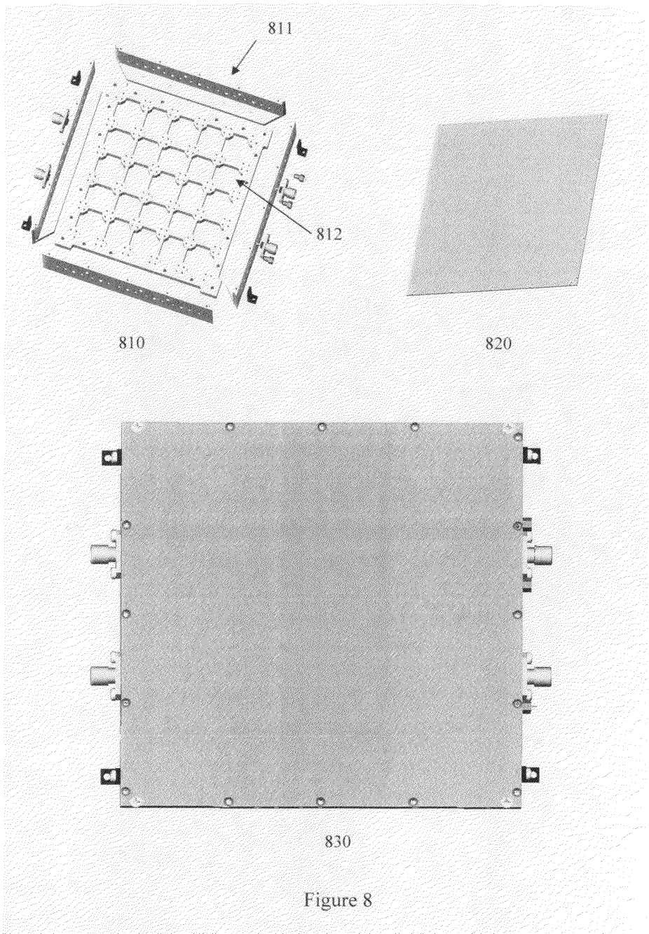

FIG. 8 shows an assembled 5×5 array module. With the reference of FIG. 8, an assembled 5×5 array module (830) may include a 5×5 array base (812), a standard side wall (811) and a cover (820). The standard side wall includes standard multiple connectors, DC feed-through and ground pole positions.

As shown by the various configurations and embodiments illustrated in FIGS. 1-8, a system, method and apparatus for a general RF and Microwave circuit prototyping and integration have been described.

While preferred embodiments of the present subject matter have been described, it is to be understood that these embodiments described are illustrative only and that the scope of the invention is to be defined solely by the claims when accorded a full range of equivalence.

1. Method and apparatus for rapid and dynamic RF and Microwave circuit prototyping and integration comprises a single cell test fixture; include a standard single printed circuit board (PCB) cell and a standard single mechanical cell.

2. The standard PCB cell of claim 1 is designed to have the common input/output locations, common mounting locations, and common DC/control locations with common connectors. The standard PCB cell size is 20×20 mm², but are not limited to 20×20 mm², as they can be of any multiple size of 20×20 mm².

3. The method and apparatus for rapid and dynamic RF and Microwave circuit prototyping and integration further comprise a dynamic test fixture of any shape and can be made by the combination of many single mechanical cells, single joint cells and single PCB cells, or a big PCB with the size of multiple standard PCB size.

4. The method and apparatus for rapid and dynamic RF and Microwave circuit prototyping and integration further comprise a single assembled module, which includes a standard mechanical cell, a standard PCB cell, standard sidewalls and a cover.

5. The standard single mechanical cell of claim 1 is designed to support claim 2, claim 3 and claim 4 simultaneously. The standard single mechanical cell is designed to support the standard single PCB cell. The standard single mechanical cell is designed for any shape and any size that can be connected together by many single standard mechanical cells and single standard joint cells. The standard single mechanical cell is designed to be connected by standard sidewalls to have the assembled modules. The standard single mechanical cell is also designed to support standoffs.

6. The method and apparatus for rapid and dynamic RF and Microwave circuit prototyping and integration further comprise a standard 5×5 mechanical array cell, though not limited to the 5×5 size.

7. The method and apparatus for rapid and dynamic RF and Microwave circuit prototyping and integration further comprise a dynamic of any shape of a multiple 5×5 array size.

8. The method and apparatus for rapid and dynamic RF and Microwave circuit prototyping and integration further comprise an assembled 5×5 array module, but may also include a 5×5 mechanical array cell, sidewalls and a cover.

9. The standard 5×5 mechanical array cells of claim 6 may be mounted with the single PCB cells of claim 2. The standard 5×5 mechanical array is designed to be connected with standard array joint to have any shape and any size of multiple 5×5 arrays of claim 7. The standard 5×5 mechanical array is designed to be connected with standard sidewalls to build the single assembled 5×5 array module of claim 8. The standard 5×5 mechanical array cell is also designed to support standoffs.
